(19) United States
(12) Patent Application Publication
(10) Pub. No.: US 2020/0044100 A1
(43) Pub. Date: Feb. 6, 2020

(54) Method For Texturing A Surface Of A Semiconductor Material And Device For Carrying Out The Method

(71) Applicant: RENA TECHNOLOGIES GMBH, GUETENBACH (DE)

(72) Inventors: BENEDIKT STRAUB, SASBACH-JECHTINGEN (DE); JOHN BURSCHIK, VOERSTETTEN (DE); WOLFGANG DUEMPELFELD, SEXAU (DE); HOLGER KUEHNLEIN, VOERSTETTEN (DE)

(21) Appl. No.: 16/484,849

(22) PCT Filed: Feb. 8, 2018
(86) PCT No.: PCT/DE2018/100110

§ 371 Date: Aug. 9, 2019

(30) Foreign Application Priority Data
Feb. 9, 2017 (DE) 10 2017102 632.0

(51) Int. Cl. H01L 31/0236; H01L 21/67; H01L 31/18; H01L 21/677; C25F 3/12

(52) U.S. Cl. CPC H01L 31/02363; H01L 21/67086; C25F 3/12; H01L 21/6776; H01L 31/186; H01L 31/1876

(57) ABSTRACT

A method textures at least one portion of a surface of a semiconductor material, according to which the at least one portion of the surface is brought into contact with an etching solution. The portion of the surface is electrically conductively connected to a plus pole of a current source and is used as a positive electrode. A negative electrode located in the etching solution is electrically conductively connected to a minus pole of the current source and electric current is carried from the plus pole to the minus pole and the at least one portion of the surface is thus electrochemically etched. A device is provided for carrying out the method.

The invention relates to a method of texturing at least a portion of a surface of a semiconductor material according to the preamble of claim 1 and to an apparatus for conducting this method according to the preamble of the independent product claim.

In the manufacture of semiconductor components using semiconductor materials, wet-chemical etching methods are very frequently used, by means of which the surfaces of the semiconductor materials are treated. In the production of solar cells in particular, one way of doing this is texturing the surfaces of semiconductor materials in order to reduce reflection of incident light at the surface. In the case of solar cells, it is possible in this way to improve the coupling of light into the solar cell and to increase the efficiency of the solar cell.

The semiconductor materials used in the manufacture of semiconductor components are generally in the form of semiconductor substrates, which are understood to mean flat bodies having two sides of large area. Such substrates are sometimes referred to as semiconductor wafers, and regularly as wafers. Such a substrate need not necessarily consist of a solid material, as is the case for a silicon wafer. In the present context, a substrate is in principle also understood to mean a carrier substrate with a semiconductor layer arranged thereon. If the semiconductor material is in the form of substrates, these substrates frequently have a sawn surface. This is the case especially for substrates made of solid material, for example the silicon wafers mentioned, since these are generally cut down from a block of a semiconductor material. But even when semiconductor material is in another shape, a sawn surface is often present.

Semiconductor materials are typically sawn using wire saws. The wire saw used may be a wire which is moved in a separation medium slurry, or a diamond-studded wire. If a diamond-studded wire is used, this is referred to in the present context as diamond wire saw or diamond wire sawing. Wire-sawn semiconductor materials have a certain roughness at their cut faces. The sawing operation partly pulverizes the semiconductor material, and so there are resultant losses of semiconductor material. These losses are greater in the case of the above-described slice lapping method with the wire moving in the separation medium suspension than in the case of diamond wire sawing. For this reason, the use of diamond wire saws is an increasingly important aim.

In the industrial manufacture of solar cells, especially silicon solar cells, texturing of the silicon substrates by means of wet-chemical etching using an aqueous etch solution containing hydrogen fluoride and nitric acid has been found to be useful. In this case, the rough surface present as a result of the wire sawing, called the saw damage, is converted to a surface structure having reduced reflection. In the case of semiconductor materials that have been sawn by means of the above-described slice lapping method, it is possible by this texturing method to produce very good textures. However, it has been found that, in the case of diamond wire-sawn semiconductor materials, these texturing methods do not lead to the desired result. The formation of a good texture is apparently hindered in that saw damage in the case of diamond wire-sawn semiconductor material is much less marked. Alkaline texture etch solutions are not appropriate in the case of polycrystalline materials and hence do not constitute an alternative at least for these semiconductor materials.

Against this background, it is an object of the present invention to provide a method by means of which semiconductor materials having a less rough surface can be textured reliably and adequately.

This object is achieved by a method having the features of claim 1.

It is a further object of the invention to provide an apparatus for performing this method. This is achieved by an apparatus having the features of the independent apparatus claim.

Advantageous developments are each the subject of dependent claims.

The method of the invention for texturing at least a portion of a surface of a semiconductor material envisages that the at least a portion of the surface is contacted with an etch solution. In addition, the at least a portion of the surface is connected in an electrically conductive manner to a plus pole of a power source and used as positive electrode. A negative electrode disposed in the etch solution is connected in an electrically conductive manner to a minus pole of the power source. By conducting electrical current from the plus pole to the minus pole, the at least a portion of the surface is electrochemically etched.

In this method, the etch solution serves simultaneously as electrolyte, and so the electrical current can be conducted through the etch solution. The electrical current is capable of replacing the oxidizing agent, frequently nitric acid, otherwise present in texturing etch solutions, in that it provides electrical holes at the surface of the semiconductor material. These enable a reaction with the etch solution and hence the texturing of the surface of the semiconductor material.

The etch solution used is preferably an acidic solution. It is more preferably an aqueous solution containing hydrogen fluoride.

Preference is given to texturing polycrystalline semiconductor material since alkaline etch solutions are not usable for this material.

The method has been found to be particularly useful in the texturing of silicon. Therefore, the semiconductor material used is advantageously silicon, more preferably polycrystalline silicon.

The operation of the electrochemical etching is now illustrated by a working example in which silicon is present as semiconductor material and the etch solution used is an aqueous solution containing hydrogen fluoride. As already elucidated, the electrically conductive connection of the at least a part of the surface to the plus pole of the current source provides electrical holes at the at least a portion of the surface. These are referred to hereinafter as h⁺ for short. The hydrogen fluoride in the etch solution provides fluorine ions F⁻ there. At the at least a part of the surface, this then results in the reaction

Si+6F⁻+4h⁺→SiF₆.

This constitutes the electrochemical etching operation. The electrical current is distributed homogeneously on the at least a portion of the surface. As a result, etch peaks and etch valleys are formed, which in turn leads to formation of pores.

Preferably essentially only a lateral face on the underside of the semiconductor material is textured. For this purpose, essentially only that lateral face on the underside, which is sometimes referred to hereinafter merely as underside for short, is contacted with the etch solution. In other words, the lateral surface on the underside mentioned could be referred to as the surface of the semiconductor material that points downward. By means of the procedure described, it is possible to achieve single-sided texturing of the semiconductor material. By comparison with full-area or double-sided texturing of the semiconductor material, this enables a reduction in texturing complexity as a result of lower chemical and power consumption. Moreover, single-sided texturing has been found to be useful in various semiconductor component manufacturing methods, especially solar cell production methods.

Preference is given to texturing at least a portion of a surface of a substrate, preferably a solar cell substrate. What is meant by a substrate in the present context, and the fact that the substrate need not necessarily consist of a solid material but that a carrier substrate with a semiconductor disposed thereon also constitutes such a substrate, has already been set out above. The method of the invention has been found to be particularly useful in the texturing of substrates.

Preferably, by means of the electrochemical etching, a microporous semiconductor material structure is formed. The structures thereof have a size in the range from 0.2 to 3 μm. With microporous structures of this kind, it was possible to achieve textures with very small reflection values. In principle, it is alternatively also possible to form micro- or mesoporous structures if viable in the respective application.

It has been found to be advantageous to use an etch solution containing at least one surfactant. For example, the surfactant used may be a product having the Suract C125 trade name. By means of the surfactant content in the etch solution, it is possible to influence a shape of the structures formed in the electrochemical etching. It is especially possible to influence the size of pores formed.

Preference is given to cutting the semiconductor material from a semiconductor material body by means of a wire saw and subsequently texturing a cut face of the semiconductor material. It has been found that such cut faces can be textured reliably and efficiently. The wire saw used is more preferably a diamond wire saw. In this connection, the method of the invention has been found to be particularly advantageous since even cut surfaces having reduced roughness that result in the case of diamond wire sawing can be textured reliably and efficiently. What is meant in the present context by a diamond wire saw has been set out in the introduction.

In a preferred execution variant, the semiconductor material is transported, in a continuous plant, through multiple baths containing the etch solution that are arranged in succession in a transport direction. The transport here can be effected in such a way that the semiconductor material is immersed completely into the etch solution present in the tanks, or in such a way that only a portion of the surface of the semiconductor material is brought into contact with the etch solution disposed in the tanks. The latter especially enables essentially single-sided texturing of the semiconductor material. During the transporting of the semiconductor material through the multiple tanks, the at least a portion of the surface of the semiconductor material is at times simultaneously contacted with the etch solution from two tanks arranged in succession in transport direction. During the existence of the simultaneous contact with the etch solution from the two tanks mentioned, a positive electrode disposed in the etch solution in a first of the two tanks mentioned is connected in an electrically conductive manner at least at times to the plus pole of a power source and additionally, in a second of the two tanks mentioned as well, the negative electrode disposed in the etch solution is connected in an electrically conductive manner to the minus pole of the power source, and the electrical current is conducted from the positive electrode disposed in the first tank through the semiconductor material to the negative electrode disposed in the second tank.

In this way, the method can be conducted on an industrial scale in a continuous plant. During the existence of the simultaneous contact described, via the contact with the etch solution in the first tank, the region in contact with the etch solution from the second tank becomes the positive electrode in the second tank. As a result, in the second tank, the above-described electrochemical etching operation can proceed and electrochemical etching can be effected in the second tank. Contact connection of the at least a portion of the surface of the semiconductor material is effected here without moving parts in a comfortable manner via the etch solution disposed in the first tank. The maintenance complexity for the contacting apparatus is therefore low. There is additionally avoidance of attack on customary contact mechanisms, for example sliding contacts or the like, by aggressive vapors emanating from the etch solution, for example hydrogen fluoride vapors. Shutdown and maintenance periods on plants used for performance of the method can be reduced in this way.

In one development, in a tank of the multiple tanks mentioned which is disposed at the start of the continuous plant viewed in transport direction and in a tank of the multiple tanks mentioned which is disposed at the end of the continuous plant in transport direction, the way in which electrical current proceeding from or leading to the electrodes disposed in these tanks is conducted depends on the position of the semiconductor material. The current flows in the tank disposed at the start of the continuous plant and the tank disposed at the end of the continuous plant are thus switched on and off depending on the position of the semiconductor material. In this way, it is possible to compensate for inhomogeneities in the textile formed which result from the need to conduct a top end of the semiconductor material, or of the substrate, first through the tank disposed at the start of the continuous plant before the top end reaches the second tank and the electrochemical etching can be commenced. The lower sections of the semiconductor material, or of the substrate, that are thus still present in the tank disposed at the start of the continuous plant are thus textured, whereas the top region remained untextured at first. In the tank of the multiple tanks mentioned disposed at the end of the continuous plant, an analogous imbalance arises in the treatment of the top end and the lower sections. After passing through the continuous plant, the semiconductor material, or the substrate, has thus been electrochemically etched for different periods in a middle region than in a top region and in an end region. These imbalances can be compensated for by controlling the electrical current supply in the tank disposed at the start and the tank disposed at the end in the manner described above depending on the position of the semiconductor material.

Another way of compensating for the imbalances described is to control the conducting of the electrical current with open-loop or closed-loop control in such a way that, in each of the multiple tanks mentioned, a ratio of the area of the at least a portion of the surface of the semiconductor material which is in contact with the etch solution in a particular tank to an electrical current flowing in the particular tank is constant. This condition of constancy is fulfilled here for the particular tank during periods in which the at least a portion of the surface is in contact with the etch solution present in the particular tank. If a single tank of the multiple tanks mentioned is considered, this means the following for this individual tank: if the etch solution present in this individual tank is in contact with the at least a portion of the surface of the semiconductor material, the condition of constancy is fulfilled for this tank. What the condition of constancy says for this individual tank is that the ratio of the area of the at least a portion of the surface of the semiconductor material which is in contact with the etch solution present in this individual tank to the electrical current flowing in this individual tank is constant.

In the case of the above-elucidated periods of the electrochemical etching of different lengths, for the sake of simplicity, it has been assumed that, in each tank of the multiple tanks, the etch solution disposed in this tank is contacted with the at least a portion of the surface of the semiconductor material simultaneously at least at times with an etch solution disposed in an adjacent tank of the multiple tanks. This is not absolutely necessary, but enables a comparatively simple and uncomplicated method regime.

The more adjacent tank pairs are present in which there is electrochemical etching in simultaneous contact with the etch solutions present therein, the smaller the imbalances described in the electrochemical etching times. An increase in a transport speed with which the semiconductor materials are transported through the continuous plant in transport direction can also reduce the imbalances described. If the aim is short process times and consequently high densities at the at least a portion of the surface of the semiconductor material, the imbalances described are nevertheless not negligible. An alternative way of balancing out the imbalances described is to match the lengths of the tanks of the multiple tanks disposed at the start of the continuous plant and that disposed at the end of the continuous plant. The term “length” refers to the length of the tanks in question in transport direction. This option is described in more detail hereinafter.

In an alternative execution variant, the semiconductor material, in a continuous plant, is transported through a tank containing the etch solution in which the negative electrode is disposed. The at least a portion of the surface of the semiconductor material is contacted here with the etch solution. During that period, the at least a portion of the surface is connected in an electrically conductive manner to the plus pole of the power source and electrical current is conducted from the plus pole to the minus pole. The electrically conductive connection of the at least a portion of the surface of the semiconductor material to the plus pole can in principle be implemented in any manner known per se, for example by means of sliding contacts or contact arms included in the continuous plant.

In the method of the invention, the electrochemical etching operations proceed comparatively slowly compared to a wet-chemical texturing method known per se using an etch solution comprising hydrogen fluoride and nitric acid. Preference is therefore given to electrochemical etching for more than eight minutes.

Against this background, a development of the method of the invention that has been found to be advantageous is one in which the at least a portion of the surface of the semiconductor material is first electrochemically etched in one of the ways described above. Subsequently, the at least a portion of the surface of the semiconductor material is etched by means of an aqueous texture etch solution containing hydrogen fluoride and nitric acid. In this way, especially in the case of diamond wire-sawn semiconductor materials, good textures can be produced with reduced method duration. Etch times of one to two minutes have been found to be useful in this connection in the initial electrochemical etching.

Particular preference is given to another electrochemical etching after the etching by means of the aqueous texture etch solution described. In the case of this electrochemical etching step too, etching times of one to two minutes have been found to be useful. As has been found, by means of this new electrochemical etching operation, it is possible to further reduce reflections of incident light at the at least a portion of the surface of the semiconductor material.

In an alternative execution variant of the method of the invention, prior to the electrochemical etching, the at least a portion of the surface of the semiconductor material is etched by means of an aqueous texture etch solution containing hydrogen fluoride and nitric acid. It has been found that it is possible in this way, in suitable applications, likewise to combine shortening of the method duration with satisfactory textures, especially in diamond wire-sawn semiconductor material. In this execution variant, preference is given to electrochemical etching for a duration of one to two minutes.

Moreover, it has been found that it can be advantageous in individual applications to combine the electrochemical etching with etching by means of the aqueous texture etch solution mentioned in one of the ways described in order to ensure that saw damage present on the semiconductor material is completely removed.

The apparatus of the invention has a transport apparatus by means of which objects to be treated are transportable in a transport direction. In addition, multiple tanks each containing a treatment liquid, and in which at least one electrode is disposed, are provided in successive arrangement in transport direction.

By means of this apparatus, the method of the invention can be conducted as a continuous method. The treatment liquid provided may be an etch solution, preferably an acidic etch solution and more preferably a hydrogen fluoride-containing etch solution.

In one development, in any two immediately successive tanks of the multiple successive tanks in transport direction, the at least one electrode that belongs to a first tank of these two immediately successive tanks has a first polarity and the at least one electrode that belongs to a second tank of these two immediately successive tanks has a second polarity that is the opposite of the first polarity. The immediately successive arrangement of two of the multiple tanks is understood here to mean that no other tank of the multiple tanks is arranged between them. Other components, for example transport rolls, may quite possibly be provided between tanks in an immediately successive arrangement. In the case of this configuration variant, a section of the object to be treated may be used as electrode in an electrochemical etching operation. It is possible to dispense with conventional contact connection apparatuses, for example sliding contacts.

Advantageously, a first tank viewed in transport direction of the multiple successive tanks in transport direction and a last tank viewed in transport direction of the multiple successive tanks in transport direction have lengths extending in transport direction that differ from lengths of the other multiple successive tanks in transport direction. These lengths of the first and last tanks are preferably extended. In this way, it is possible to balance out the above-described effect that different regions of the object to be treated are electrochemically etched for different periods of time with a low level of extra complexity. Apart from the first and last tanks of the multiple successive tanks in transport direction, all tanks of the multiple tanks arranged in succession in transport direction more preferably have a uniform length. Manufacturing complexity can be reduced in this way.

In a preferred configuration variant, apart from the first tank and the last tank, all tanks of the multiple tanks in successive arrangement in transport direction have a uniform length extending in transport direction and a uniform clear opening length P extending in transport direction. Two immediately successive tanks of the multiple tanks mentioned are each spaced apart from one another by a length T. A clear opening length of the first and last tanks compared to the other tanks of the multiple tanks mentioned is extended by a differential length L. In the case of an object to be treated that has a length O extending in transport direction, this is calculated by

L=O-2T-P-C.

C here is a parameter chosen in a process- and/or material-dependent manner such that any point on a surface of the substrate to be treated is treated for an equal time. It has been found that, with this apparatus, the described imbalances in the treatment times, or electrochemical etching times, can be largely balanced out. For the parameter C, the values of 0 2 have been found to be useful, especially in the treatment of silicon substrates and silicon solar cell substrates.

The invention is elucidated in detail by figures hereinafter. Where appropriate, elements having the same effect are given the same reference numerals. The invention is not limited to the working examples shown in the figures—not even in relation to functional features. The description so far and also the description of figures which follows contain numerous features, of which several have been expressed collectively in some cases in dependent claims. However, these features and also all other features disclosed above and in the description of figures that follows will also be considered individually by the person skilled in the art and combined to give viable further combinations. More particularly, all the features mentioned are each combinable individually and in any suitable combination with the method and/or the apparatus of the independent claims. The figures show:

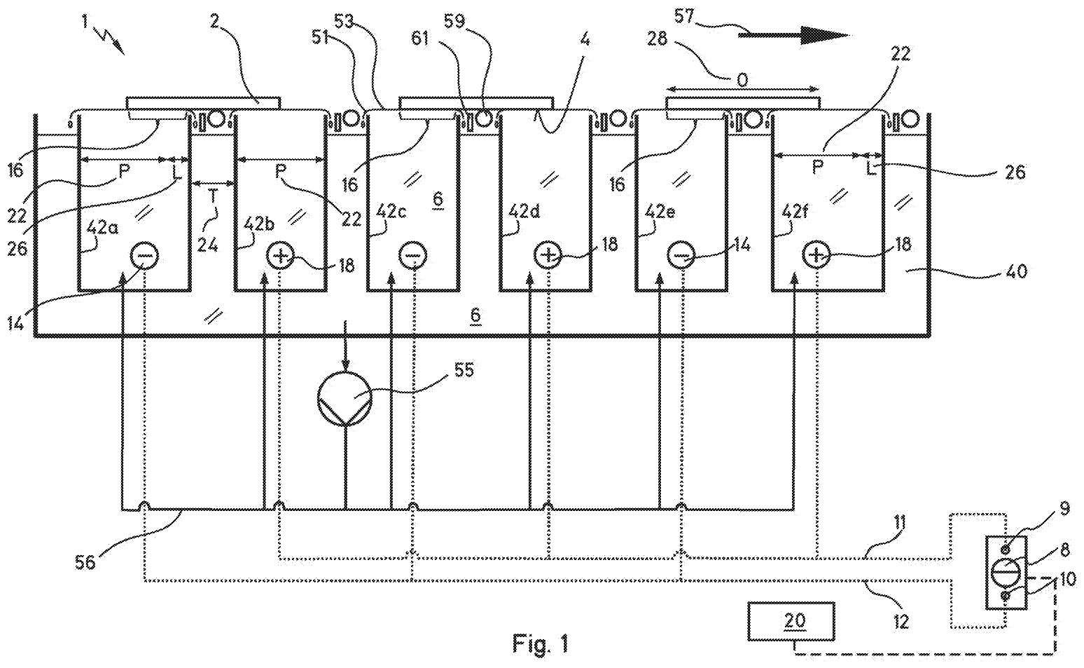

FIG. 1 a first working example of the method of the invention and of the apparatus of the invention in a schematic diagram

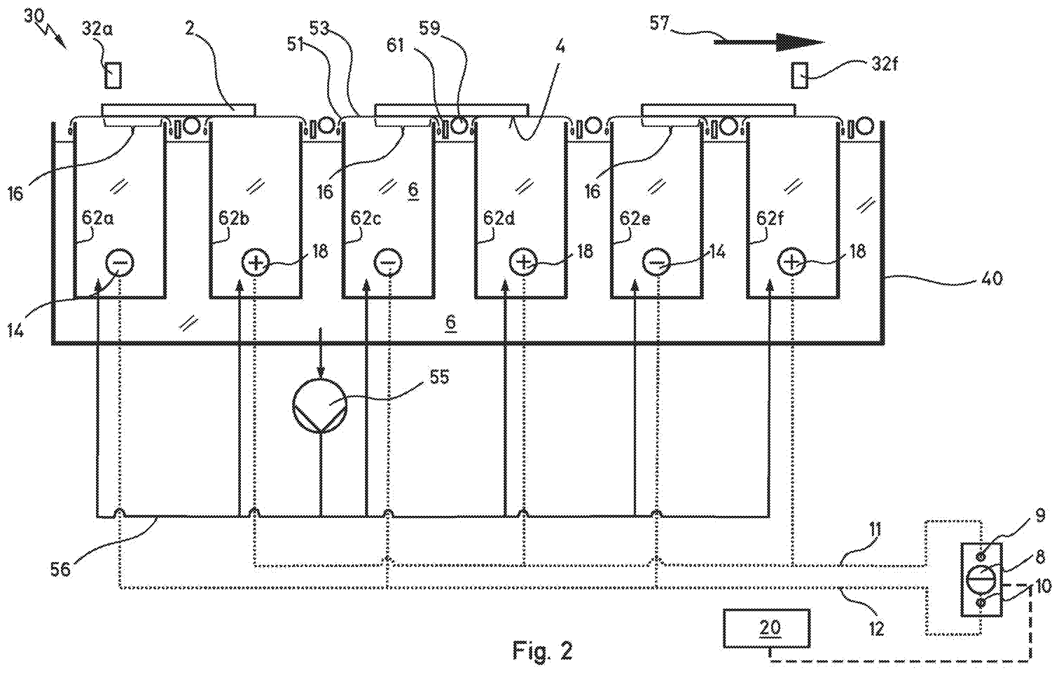

FIG. 2 schematic diagram of a second working example of the apparatus of the invention and of the method of the invention

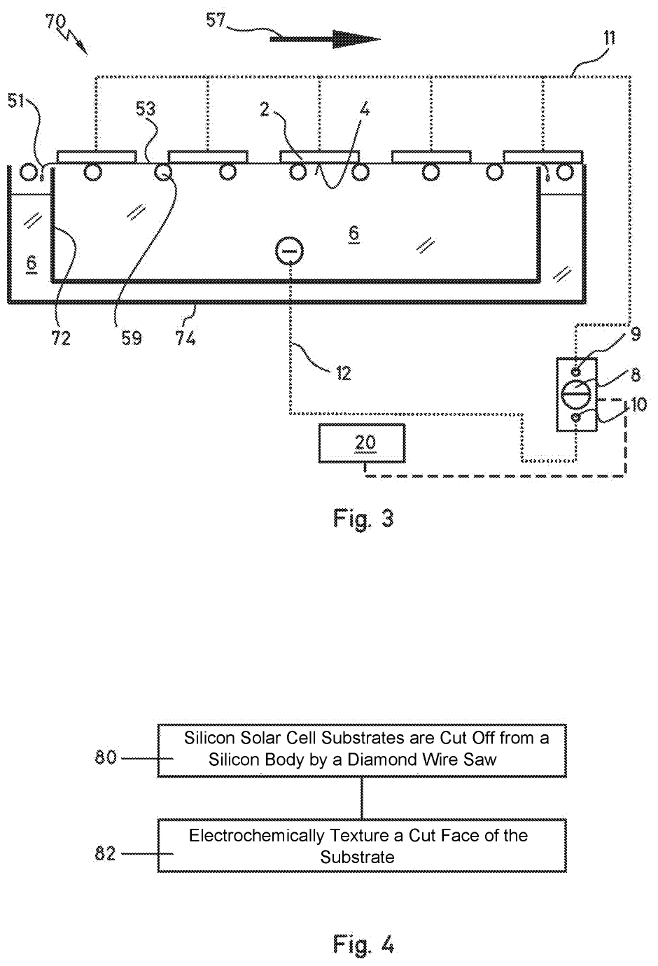

FIG. 3 a third working example of the method of the invention in schematic view

FIG. 4 flow diagram of a fourth working example of the method of the invention

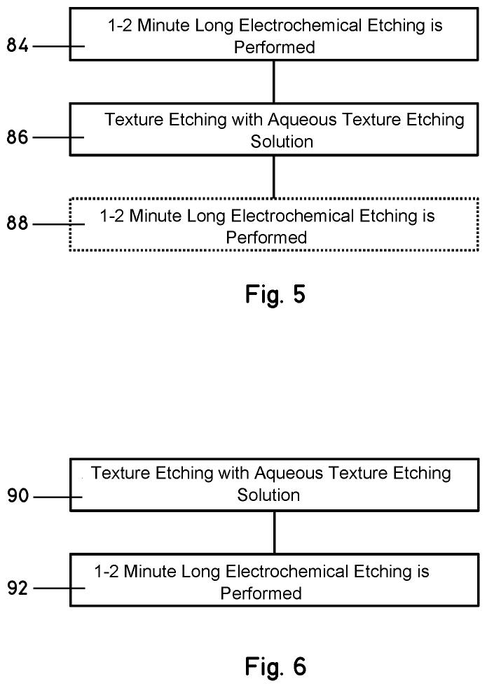

FIG. 5 flow diagram of a fifth working example of the method of the invention

FIG. 6 flow diagram of a sixth working example of the method of the invention

FIG. 1 illustrates, in a schematic diagram, a first working example of the method of the invention and a first working example of the apparatus of the invention for performance of said method. The continuous plant 1 shown has a transport apparatus having, as an essential constituent, transport rolls 59 on which the objects, in the present working example silicon solar cell substrates 2, are transportable in a transport direction 57 through the continuous plant 1. Other constituents of the transport apparatus that are known per se are not shown for the sake of better clarity. Multiple tanks 42a to 42f are provided successively in transport direction 57. These each contain a treatment liquid which, in the present working example, is a hydrogen fluoride-containing etch solution 6 in which there are in turn disposed electrodes 14, 18. Every two adjacent tanks 42a to 42f here have electrodes 14, 16 of different polarity. The negative electrode 14 in tank 42a is thus followed by a positive electrode 18 in tank 42b. The same applies to the other tanks 42c to 42f. The negative electrodes 14 are connected to a minus pole 10 of a power source 8 by means of feeds 12 to a minus pole. Correspondingly, the positive electrodes are connected to a plus pole 9 of the power source 8 via feeds 11 to the plus pole. According to the application and method regime, in the case of the feeds 11, 12, a separate feed may be provided for each electrode 14, 18, or multiple electrodes 14, 18 of the same polarity are fed by means of a common feed. The supply of power is controlled by means of a control device 20 connected to the power source 8, where the control device 20 may also be executed as a closed-loop control device.

The continuous plant 1 is designed for single-sided treatment, more specifically for single-sided texturing, of the silicon solar cell substrates 2. Lateral faces 4 on the underside of the silicon solar cell substrates 2, or the underside thereof for short, are contacted with the etch solution 6 present in the tanks 42a to 42f. For this purpose, etch solution is constantly pumped from a collecting tank 40 by means of a fluid pump 55 through pipelines 56 into the tanks 42a to 42f. As a result, a higher liquid level 53 which is brought into contact with the lateral face 4 on the underside of the silicon solar cell substrates 2 is established in the tanks 42a to 42f compared to the collecting tank 40. Overflowing etch solution 51 runs out of the tanks 42a to 42f into the collecting tank 40 and thence can be fed back to the tanks 42a to 42f again.

The etch solution disposed in the tanks 42a to 42f acts as electrolyte and brings about an electrically conductive connection between the lateral face 4 on the underside of the silicon solar cell substrates 2 and the electrodes 14, 18 disposed in the tanks 42a to 42f and hence ultimately to the minus pole 10 and the plus pole 9 of the power source 8. If the silicon solar cell substrates are transported through the continuous plant 1 in transport direction 57, the lateral faces 4 on the underside of the silicon solar cell substrates are contacted simultaneously at times with the etch solution 6 from two tanks 42a to 42f arranged in succession in transport direction 57. The representation of FIG. 1 illustrates such a juncture. Right-hand sections of the lateral faces 4 on the underside of the silicon solar cell substrates are in contact with the etch solution from tanks 42b, 42d and 42f, while left-hand sections are in contact with the etch solution from tanks 42a, 42c and 42e. The right-hand sections of the lateral faces 4 on the underside connect the silicon solar cell substrates via the etch solution 6 in an electrically conductive manner to the positive electrodes 18 and consequently to the plus pole 9 of the power source. As a result, the left-hand sections of the lateral faces on the underside serve as positive electrodes 16 in the tanks 42a, 42c, 42e. Electrical current is thus conducted from the plus pole 9 of the current source 8 via the silicon solar cell substrates 2 to the minus pole 10 of the current source 8, and the lateral face 4 on the underside is electrochemically etched in the sections 16 that serve as positive electrode. This forms a microporous semiconductor structure. In principle, it is alternatively also possible to form micro- or mesoporous structures. These structures constitute a texture, and so the lateral face 4 on the underside of the silicon solar cell substrates is textured.

If a silicon solar cell substrate 2, in the representation of FIG. 1, is transported coming from the left into the continuous plant 1, the lateral face 4 thereof on the underside is at first contacted solely with the etch solution 6 from tank 42a. As soon as the silicon solar cell substrate 2 does not receive any electrically conductive connection to the plus pole 9 of the power source 8, no electrochemical etching operation is established. Only when the right-hand portion of the silicon solar cell substrate 2 reaches the tank 42b can current be conducted from the plus pole 9 through the tank 42a to the minus pole 10 and the electrochemical etching operation proceed. As a result, the right-hand portion of the silicon solar cell substrate, which could also be referred to as the top end, is not electrochemically etched in tank 42a. An analogous imbalance in the etching of different sections of the lateral face 4 on the underside is found in the last tank 42f. In order to balance out this imbalance, in the working example of FIG. 1, the first tank 42a and the last tank 42f, compared to the other tanks 42b to 42e having a uniform length and a uniform clear opening length P 22 are extended by a differential length L 26. This is calculated from a length O 28 of the silicon solar cell substrates 2 that are to be treated, more specifically textured, and a separation T 24 of the uniformly spaced apart tanks 42a to f of said clear opening length P 22 by

L=O-2T-P-C.

C is a parameter suitably chosen in the manner described above. In the working example of FIG. 1, the value of 0 was chosen therefor.

The effect of the separation T between two adjacent tanks 42a to 42f is that, in the region between two tanks 42a to 42f, the lateral face 4 on the underside of the silicon solar cell substrates 2 is not in contact with etch solution 6. In this way, it is possible to avoid a short circuit between adjacent tanks 42a to 42f. In order to increase short-circuit security, in the working example of FIG. 1, an optional airknife 61 is provided downstream of each of the tanks 42a to 42f, by means of which remaining etch solution can be blown off.

FIG. 2 illustrates a further working example of the method of the invention and also of the apparatus of the invention. The continuous plant 30 shown differs from the continuous plant 1 from FIG. 1 in that tanks 62a to 62f of uniform length are provided. Additionally provided are position detection devices 32a, 32f that are connected by means of the control device 20. Representation of these connections was dispensed with in FIG. 2 for better clarity. By means of the position detection devices 32a, 32f mentioned, positions of the silicon solar cell substrates 2 are detected and the flow of electrical current in tanks 62a and 62f is controlled by means of the current controller 20 depending on the position thereof. In this way, it is possible to compensate for the above-described imbalance in the electrochemical etching, or texturing, of left-hand, middle and right-hand regions of the silicon solar cell substrates in tanks 62a and 62f.

FIG. 3 illustrates, in a schematic diagram, a further working example of the method of the invention. By contrast with the examples from FIGS. 1 and 2, only one tank 72 is provided here. This is again fed by means of a fluid pump from the collecting tank 74, and so the overflowing etch solution 51 is present here too. Representation of the fluid pump and accompanying pipelines has been dispensed with in FIG. 3 for better clarity. FIG. 3 shows a continuous plant in which the silicon solar cell substrates 2 and hence also the lateral faces 4 thereof on the underside are connected to the plus pole 9 of the power source by means of the feeds 11 to the plus pole. However, by contrast with the continuous plant from FIGS. 1 and 2, a contact device is required for each silicon solar cell substrate 2. For this purpose, there are in principle multiple options known per se, and so the contact device is not shown in detail in FIG. 3. For example, contact arms or sliding contacts that run with the silicon solar cell substrates 2 may be provided. In the working example of FIG. 3, with the current source 8 switched on, electrical current is conducted constantly from the plus pole 9 to the minus pole if at least one silicon solar cell substrate is present at least partly above the tank 72.

A further working example of the method of the invention is illustrated by the flow diagram of FIG. 4. In this working example, silicon solar cell substrates are first cut off 80 by means of a diamond wire saw from a silicon body, for example a silicon block. Subsequently, a cut face of the silicon solar cell substrates is electrochemically textured 82. This can be effected, for example, by means of one of the methods described in the working examples of FIGS. 1 to 3. It is possible here to use the continuous plants 1, 30, 70 shown in schematic form in the respective working examples. The method of the invention and also the apparatus of the invention have been found to be particularly advantageous in the texturing of semiconductor materials covered by means of diamond wire saws, especially silicon solar cell substrates.

As elucidated above, etch rates are comparatively low in the electrochemical etching according to the invention. In the working example shown in the flow diagram of FIG. 5, therefore, initial electrochemical etching 84 for one to two minutes is envisaged. This can be implemented, for example, by the methods and apparatus as elucidated in FIGS. 1 to 3. This is then followed by texture etching 86 with an aqueous texture etch solution containing hydrogen fluoride and nitric acid. By this method variant, it is also possible in the case of diamond wire-sawn semiconductor materials to reliably produce textures with low reflection. For a further reduction in reflection, the working example of FIG. 5 provides for an optional step of another electrochemical etching operation 88 over a duration of one to two minutes. Analogously to the initial electrochemical etching, this method step can also be conducted by the method examples and apparatus examples elucidated by FIGS. 1 to 3.

FIG. 6 illustrates, using a flow diagram, a further working example of the method of the invention. This differs from that of FIG. 5 essentially in that initial texture etching 90 with the aqueous texture etch solution is followed by electrochemical etching 92 for one to two minutes. This electric chemical etching can again be conducted, for example, by the methods and apparatuses elucidated by FIGS. 1 to 3.

### LIST OF REFERENCE NUMERALS

1 continuous plant

2 silicon solar cell substrate

4 lateral face on underside

6 etch solution

8 power source

9 plus pole

10 minus pole

11 plus pole feeds

12 minus pole feeds

14 negative electrode

16 section serving as positive electrode

18 positive electrode

20 control device

22 clear opening length P

24 tank separation T

26 differential length L

28 length O of the silicon solar cell substrate

30 continuous plant

32a position detection device

32f position detection device

40 collection tank

42a-42f tanks

51 overflowing etch solution

53 liquid level

55 fluid pump

56 pipelines

57 transport direction

59 transport roll

61 airknife

62a-62f tanks

70 continuous plant

72 tank

74 collecting tank

80 cut silicon solar cell substrates from silicon body by means of a diamond wire saw

82 electrochemical texturing of a cut face

84 electrochemical etching for 1 to 2 minutes

86 texture etching with aqueous texture etch solution

88 electrochemical etching for 1 to 2 minutes

90 texture etching with aqueous texture etch solution

electrochemical etching for 1 to 2 minutes

1-15. (canceled)

16. A method for texturing at least a portion of a surface of a semiconductor material, which comprises the steps of:
contacting the portion of the surface with an etching solution;
connecting the portion of the surface in an electrically conductive manner to a plus pole of a power source and the plus pole functions as a positive electrode;
connecting a negative electrode disposed in the etch solution in an electrically conductive manner to a minus pole of the power source; and
conducting electrical current from the plus pole to the minus pole resulting in the portion of the surface being electrochemically etched.

17. The method according to claim 16, wherein generally only a lateral face on an underside of the semiconductor material is textured and only the lateral face on the underside is contacted by the etching solution.

18. The method according to claim 16, which further comprises texturing the portion of the surface of the semiconductor material.

19. The method according to claim 16, wherein an electrochemical etching forms a macroporous semiconductor material structure having structures with a size in a range from 0.2 to 3 μm.

20. The method according to claim 16, which further comprises forming the etching solution to contain at least one surfactant.

21. The method according to claim 16, which further comprises cutting-off the semiconductor material from a semiconductor material body by means of a wire saw and a cut face of the semiconductor material is subsequently textured.

22. The method according to claim 16, which further comprises:
transporting the semiconductor material, in a continuous plant, through plurality of tanks containing the etching solution and the plurality of tanks are disposed successively in a transport direction;
contacting the portion of the surface of the semiconductor material simultaneously at times with the etching solution from two of the tanks disposed successively in the transport direction; and
during an existence of simultaneous contact with the etching solution from the two tanks, the positive electrode disposed in the etching solution in a first of the two tanks is connected in the electrically conductive manner at least at times to the plus pole of the power source and, in a second of the two tanks, the negative electrode disposed in the etching solution is connected in the electrically conductive manner to the minus pole of the power source, and the electrical current is conducted from the positive electrode disposed in the first tank through the semiconductor material to the negative electrode disposed in the second tank.

23. The method according to claim 22, wherein in a tank of the plurality of tanks which is disposed at a start of the continuous plant viewed in the transport direction and in a tank of the plurality of tanks which is disposed at an end of the continuous plant in the transport direction, a way in which the electrical current proceeding from or leading to the positive and negative electrodes disposed in the tanks is conducted depends on a position of the semiconductor material.

24. The method according to claim 16, which further comprises:
transporting the semiconductor material, in a continuous plant, through a tank containing the etching solution in which the negative electrode is disposed while the portion of the surface of the semiconductor material is being contacted with the etching solution;
connecting, in a course of transport, the portion of the surface in an electrically conductive manner to the plus pole of the power source; and
conducting the electrical current from the plus pole to the minus pole.

25. The method according to claim 16, wherein:
the portion of the surface of the semiconductor material is first electrochemically etched; and
the portion of the surface of the semiconductor material is subsequently etched by means of an aqueous texture etching solution containing hydrogen fluoride and nitric acid.

26. The method according to claim 25, wherein prior to the electrochemical etching, the portion of the surface of the semiconductor material is etched by means of the aqueous texture etching solution containing the hydrogen fluoride and the nitric acid.

27. The method according to claim 18, wherein the semiconductor material is a solar cell substrate.

28. The method according to claim 21, wherein the wire saw is a diamond wire saw.

29. The method according to claim 25, which further comprises subsequently performing a further electrochemical etching process on the portion of the surface of the semiconductor material.

30. An apparatus for texturing at least a portion of a surface of an object, the apparatus comprising:
a transport device for transporting the object to be treated in a transport direction; and
a plurality of successive tanks disposed in succession in the transport direction, each of said tanks containing a treatment liquid in which at least one electrode is disposed.

31. The apparatus according to claim 30, wherein in any two immediately successive said tanks of said plurality of successive tanks in the transport direction, said at least one electrode that belongs to a first tank of said two immediately successive tanks has a first polarity and said at least one electrode that belongs to a second tank of said two immediately successive tanks has a second polarity that is opposite of the first polarity.

32. The apparatus according to claim 30, wherein a first tank viewed in the transport direction of said plurality of successive tanks disposed in the transport direction and a last tank viewed in the transport direction of said plurality of successive tanks in the transport direction have lengths extending in the transport direction that differ from lengths extending in the transport direction of other ones of said plurality of successive tanks disposed in the transport direction.

33. The apparatus according to claim 32, wherein:
apart from said first tank and said last tank, all of said plurality of successive tanks in the transport direction have a uniform length extending in the transport direction and a uniform clear opening length P extending in the transport direction;
two immediately successive tanks of said plurality of successive tanks are each spaced apart from one another by a length T; and
a clear opening length of said first and last tanks compared to said other tanks of said plurality of successive tanks is extended by a differential length L which, in a case of the object to be treated that has a length O extending in the transport direction, is calculated by L=O-2T-P-C:
where C is a parameter chosen in a process and/or material-dependent manner such that any point on the surface of the object to be treated is treated for an equal time.

34. The apparatus according to claim 32, wherein the lengths of said first and last tank are extended in comparison to the lengths of other ones of said plurality of successive tanks.
